(19) United States
(12) Patent Application Publication
(10) Pub. No.: US 2009/0060229 A1
(43) Pub. Date: Mar. 5, 2009

(54) WIRELESS SYSTEM FOR SHARING AUDIO SIGNAL

(76) Inventors: Richard H. Harris, Beavercreek, OH (US); James E. Coch, III, Springboro, OH (US)

Correspondence Address: MEADWESTVACO CORPORATION;ATTN: IP LEGAL DEPARTMENT, 1021 MAIN CAMPUS DRIVE, RALEIGH, NC, 27606, US

(21) Appl. No.: 12/204,934

(22) Filed: Sep. 5, 2008

Related U.S. Application Data
(60) Provisional application No. 60/970,096, filed on Sep. 5, 2007.

(51) Int. Cl. H03F 99/00

(52) U.S. Cl. 381/120

(57) ABSTRACT

An audio system includes an audio enabled device, a transmitter and at least one receiver. The audio enabled device has a school and office product and an amplifier integrated with the school and office product. The audio enabled device is configured such that when the amplifier receives an electronic audio signal the amplifier and the school and office product cooperate to provide an audible audio output. The transmitter is connectable to the amplifier and configured to wirelessly transmit the electronic audio signal. Each receiver is connectable to the input port of an amplifier, and each such receiver is configured to receive the electronic audio signal transmitted by the transmitter.

### RELATED APPLICATION

This application claims domestic priority based upon U.S. Provisional Application No. 60/970096, filed Sep. 5, 2007, the contents of which are hereby incorporated by reference.

### FIELD OF THE INVENTION

The present invention is directed to a system for sharing audio signals, and more particularly, to a wireless system for sharing audio signals.

### BACKGROUND

An audio-enabled product, such as school and office product, may have an integrated amplifier. A number of audio-enabled devices, and/or amplifiers/speakers may be physically linked together by a cable in a serial or “daisy-chain” manner such that a single audio source can be provide an audible audio signal through a number of audio-enabled devices.

### BRIEF DESCRIPTION OF THE DRAWINGS

FIG. 1 is a top view of an audio source, amplifier and transmitter, with the transmitter exploded away from the amplifier;

FIG. 2 is a top view of the audio source, amplifier and transmitter of FIG. 1, with the transmitter plugged into the amplifier;

FIG. 3 is a top view of a sharing cable;

FIG. 4 is a top view of a transmitter and a plurality of receivers;

FIG. 5 is a top view of the audio source, amplifier and transmitter of FIG. 2, with the transmitter transmitting to other receivers and amplifiers;

FIG. 6 is a top view of an audio-enabled device; and

FIG. 7 is a cross section of the front cover of the device of FIG. 6, taken along line 7-7.

### DETAILED DESCRIPTION

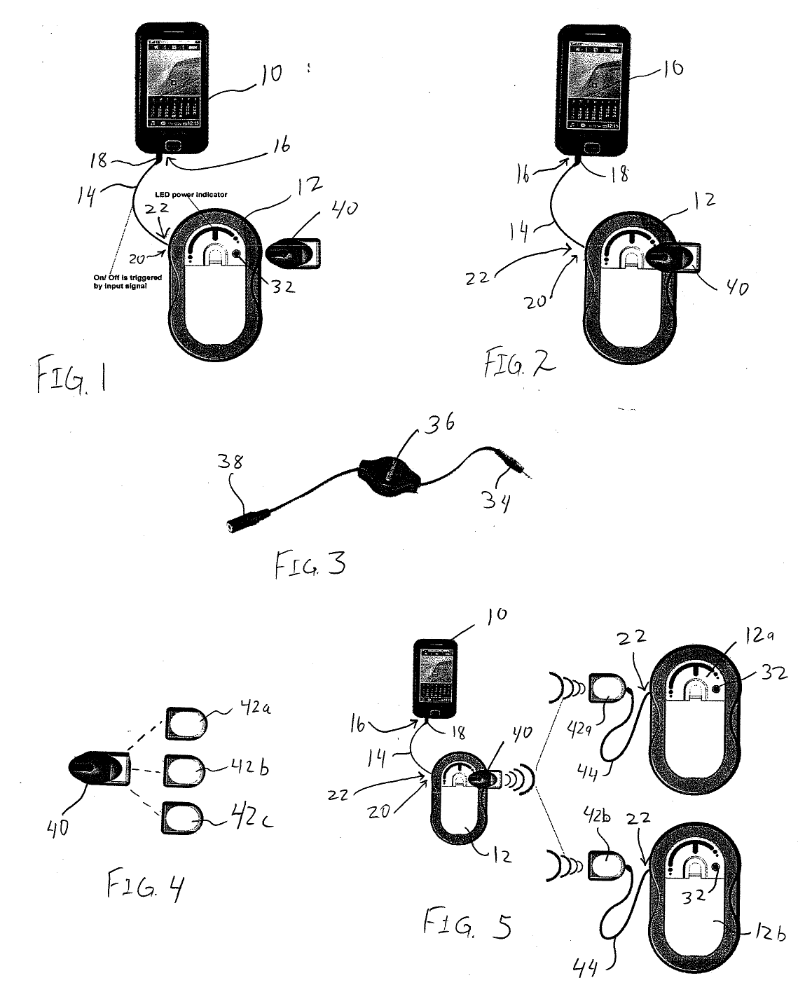

As shown in FIG. 1, an audio device or source 10, such as an MP3 player, CD player, radio, cell/mobile phone or the like may provide or generate an electronic audio signal. The audio device 10 may be operatively connectable to an amplifier 12, such as by a connector cable or cord 14 or the like to communicate the electronic audio signal to the amplifier 12. In the illustrated embodiment an “audio out” or output port 16 of the audio source 10 receives a male end 18 of the connector cord 14 therein, and an opposite, female end 20 of the connector cable 14 is operative coupled to an input or “audio in” port 22 of the amplifier 12 to communicate the electronic audio signal to the amplifier 12.

The amplifier 12 is configured to receive the electronic audio signal from the audio source 10 and modify or boost the signal as desired. The amplifier 12 may be powered by standard replaceable or rechargeable batteries or the like. Alternatively, the amplifier 12 may be provided (not shown) with a power port (e.g., USB, plug outlet) or a power cord to permit linkage with a power source. In such a case, this linkage to a power source, may recharge the amplifier, may serve as the primary power source or only power source, or may serve as a temporary power source. In addition, means to wirelessly recharge the amplifier may be added as well. As shown in FIGS. 6 and 7, the amplifier 12 may be directly coupled to, and/or integrated with a school and office product 26. In the illustrated embodiment the school and office product 26 takes the form of a folder having a front panel 24 and a rear panel 28, and the amplifier 12 is integrated into the front panel 24. However, the school or office product 26 can take any of a variety of forms besides a folder, such as a binder, notebook, notepad, portfolio, desk case, desk pad, planner, address book, date book, calendar, storage case, folder, pencil case, backpack, pad holder, file holder, pocket or the like. Moreover, the amplifier 12 can be integrated into, or coupled to, any of a variety of panels or structures of the school and office product 26 besides the front panel 12. The amplifier 12 and associated school and office product 26 together may form an audio-enabled device 30.

The amplifier 12 is typically coupled to, or integrated with, a generally flat, planar structure, such as a panel 24, 28, or other structure of the school and office product 26. In this manner the amplifier 12 and the panel 24, 28 (or other structure) cooperate to act as a speaker and create a physical manifestation of the electric audio signal in the form of an audible electronic signal/waves. U.S. Pat. Nos. 6,519,347 and 7,174,025, the entire contents of which are hereby incorporated by reference, disclose speaker technology that may be utilized in the audio-enabled device 30.

The amplifier 12 may include a share port 32 which can forward the electronic audio signal to the other devices. For example the male end 34 of a linking/sharing cable 36, as shown in FIG. 3, can be plugged into the share port 32 of the amplifier 12 and the opposite female end 38 of the sharing cable 36 can be plugged into the input port of another amplifier 12 to thereby link the two amplifiers such that they both act upon the same electronic audio signal.

In one embodiment of the present invention, a wireless transmitter 40, having a male connection configured to be received in the share port 32 of an amplifier 12, is provided. The transmitter 40 wirelessly broadcasts or transmits the electronic audio signal to one or more associated receivers 42. As shown in FIG. 5, each receiver 42a, 42b may be receivable in the female input port 22 of an associated amplifier 22a, 22b such that the wireless signal broadcast by the transmitter 40 is received by each receiver 42, and the electronic audio signal from the associated audio device 10 is thereby transmitted to the various amplifiers 12a, 12b. Each receiver 42a, 42b may have a receiver cable 44 permanently or removably coupled thereto to couple each receiver 42 to the input port 22 of the associated amplifier 12, although each cable 44 can be omitted. For example, the sharing cable 36 of FIG. 3 or other similar cables/cords may be usable as the receiver cable 44.

Each amplifier 12, 12a, 12b shown in FIG. 5 may be part of an audio-enabled device 30 (i.e. the associated school and office product 26 is not shown in FIG. 5). In this manner, the single audio source 10 of FIG. 5 provides an electronic audio signal which is converted into audible audio signals by three separate amplifiers/speakers. Moreover, the system of the present invention provides this feature without a hard-wired connection between the different amplifiers/speakers, thereby allowing great flexibility and freedom of movement of the various components.

The transmitter 40 may transmit its wireless signal by any of a wide variety of transmitting schemes, such as the Bluetooth® industrial specification for wireless personal area networks, cell phone or mobile phone technology, radio frequency communications (including AM and/or FM broadcast spectrums), transmissions in the Low-IF 2.4 GHz ISM band or the like. Moreover, each transmitter 40 may be uniquely coupled to its associated receivers 42 to avoid cross-talk between the transmitter 40 of one system and the receivers 42 of another. Alternately, or in addition, encoding may be utilized to avoid cross talk. Further, rather than having absolutely unique frequencies or encoding, a discrete number of different frequency/encodings may be utilized to minimize the chances of cross talk between differing systems.

In operation, the operator of a single audio source 10 may be able to share his or her music/audio selection with acquaintances. The operator need only plug the transmitter 40 into his or her amplifier 12, and distribute the associated receivers 42 to friends or acquaintances. The operator may distribute the receivers 42 on a temporary basis, or allow friends/acquaintances to keep the receivers 42 so that those friends/acquaintances can “listen in” to the music or other output of the audio source 10 of the operator at any time, so long as the friends/acquaintances are within range. Alternately, a single operator can utilize multiple receivers 42 with his or her own audio-enabled devices or speakers to utilize multiple speakers simultaneously (i.e. create a surround-sound environment).

In an alternate embodiment (not shown), the each amplifier 12/audio enabled device 30 has a transceiver permanently coupled thereto/integrated therein. The transceiver can both receive desired wireless signals and transmit wireless signals. Thus the integrated transceiver avoids having to plug a receiver 42 into the amplifier 12, and also avoids having to receive a cable 44 in the input port 22. In this case audio signal sharing between audio enabled devices 30 may be provided by a handshake protocol or the like. For example, each audio enabled device 30 may have, or be assigned, a unique identifier. When a first user desires to share an audio signal with a second user, the first user's transceiver may send an invitation to the transceiver of the second user. For example, the second user may receive the message “John wants to share audio with you. Accept?”

Upon an indication of acceptance, the second user's audio enabled device 30 may receive and output the electronic audio signal provided by the first user's audio enabled device 30. The audio-enabled devices 30 may enter a master-slave relationship such that the first user's audio enabled device 30 controls the second user's audio enabled device 30, until such relationship is terminated by either user.

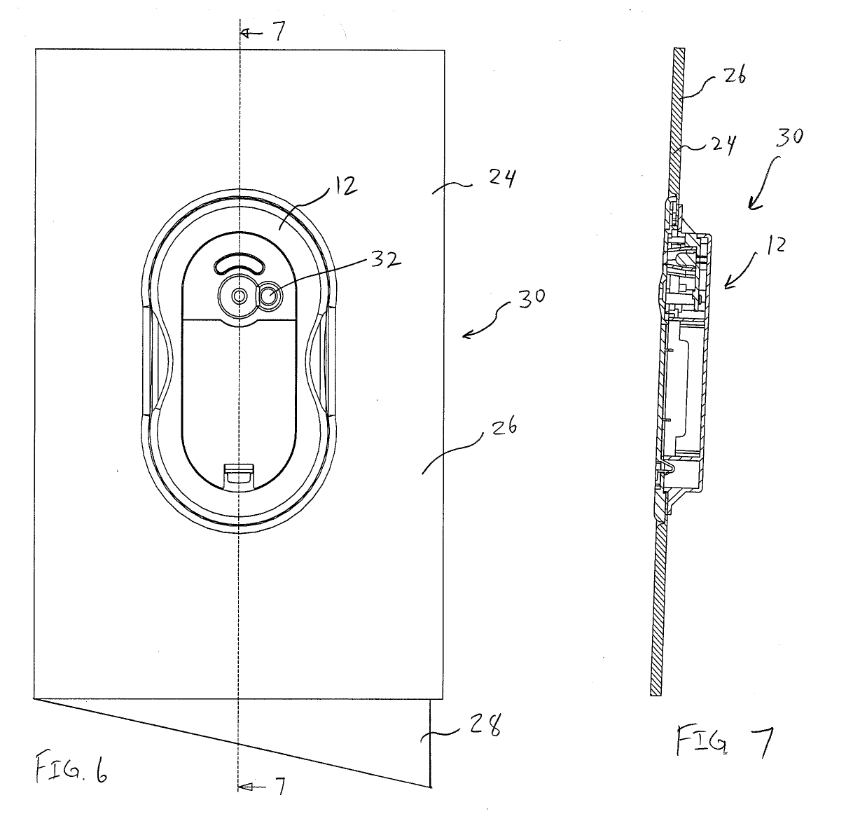

Various components of the system may be packaged together for sale. In particular, an audio-enabled device 30 may be sold along with a transmitter 40 and associated receivers 42 (i.e. three receivers 42a, 42b, 42c in the embodiment shown in FIG. 4). Alternately, the transmitter 40 and receivers 42 may be packaged and sold as a single unit (i.e. separate from the audio-enabled device 30).

Having described the invention in detail and by reference to the preferred embodiments, it will be apparent that modifications and variations thereof are possible without departing from the scope of the invention.

What is claimed:

1. An audio system comprising:
an audio enabled device including a school and office product and an amplifier integrated with the school and office product, wherein the audio enabled device is configured such that when the amplifier receives an electronic audio signal the amplifier and the school and office product cooperate to provide an audible audio output;
a transmitter connectable to the amplifier and configured to wirelessly transmit the electronic audio signal; and
at least one receiver connectable to the input port of an amplifier, wherein the receiver is configured to receive the electronic audio signal transmitted by the transmitter.

2. The audio system of claim 1 wherein the receiver is connectable to an auxiliary audio-enabled school and office product such that the electronic audio signal is convertible into an audible audio signal by the auxiliary audio-enabled school and office product.

3. The audio system of claim 1 wherein the receiver connected to an auxiliary audio-enabled school and office product such that the electronic audio signal is converted into an audible audio signal by the auxiliary audio-enabled school and office product.

4. The audio system of claim 1 wherein the school and office product is at least one of a folder, binder, notebook, notepad, portfolio, desk case, desk pad, planner, address book, date book, calendar, storage case, folder, pencil case, backpack, pad holder, file holder, or pocket having a panel which is operable as a speaker or a part thereof in conjunction with the amplifier.

5. The audio system of claim 1 wherein said transmitter is part of a transceiver which can wirelessly transmit and receive signals.

6. A method for using an audio system comprising:
accessing an audio enabled device including a school and office product and an amplifier integrated with the school and office product;
providing an electronic audio signal to said audio enabled device such that the amplifier and the school and office product cooperate to provide an audible audio signal; and
connecting a transmitter to the amplifier such that said transmitter wirelessly transmits the electronic audio signal to at least one receiver connectable to the input port of an amplifier.

7. The method of claim 6 further comprising the steps of accessing an auxiliary audio enabled school and office product including a school and office product and an amplifier integrated with the school and office product, and wherein said receiver is connected to said auxiliary audio enabled school and office product such that the auxiliary audio enabled school and office product provides an audible audio output based upon said electronic audio signal.

8. The method of claim 6 wherein the school and office product is at least one of a folder, binder, notebook, notepad, portfolio, desk case, desk pad, planner, address book, date book, calendar, storage case, folder, pencil case, backpack, pad holder, or pocket having a panel which is operable as a speaker or a part thereof in conjunction with the amplifier.
